(19) United States
(12) Patent Application Publication
(10) Pub. No.: US 2025/0255192 A1
(43) Pub. Date: Aug. 7, 2025

(54) MAGNETIC MEMORY DEVICE

(71) Applicant: Samsung Electronics Co., Ltd., Suwon-si (KR)

(72) Inventors: JAE HOON KIM, Suwon-si (KR); YOUNGCHAN KIM, Suwon-si (KR); YOUNGHYUN KIM, Suwon-si (KR)

(21) Appl. No.: 18/780,503

(22) Filed: Jul. 23, 2024

(30) Foreign Application Priority Data
Feb. 2, 2024 (KR) 10-2024-0016591

(51) Int. Cl. H10N 50/80; G11C 11/16; H10B 61/00; H10N 50/01; H10N 50/10

(52) U.S. Cl. CPC H10N 50/80; G11C 11/161; H10B 61/00; H10N 50/01; H10N 50/10

(57) ABSTRACT

Disclosed is a magnetic memory device comprising a substrate, a conductive line on the substrate, a wiring dielectric layer that covers the conductive line, a lower shield line in the wiring dielectric layer and extending in a first direction, a data storage pattern that includes a bottom electrode, a magnetic tunnel junction pattern, and a top electrode that are sequentially stacked on the lower shield line, and an upper shield line on the data storage pattern and extending in a second direction parallel to a top surface of the substrate. The second direction intersects the first direction. The lower shield line and the upper shield line include a magnetic material.

### CROSS-REFERENCE TO RELATED APPLICATION

This U.S. nonprovisional application claims priority under 35 U.S.C § 119 to Korean Patent Application No. 10-2024-0016591 filed on Feb. 2, 2024, in the Korean Intellectual Property Office, the disclosure of which is hereby incorporated by reference in its entirety.

### BACKGROUND

The present inventive concepts relate to a magnetic memory device including a magnetic tunnel junction and a method of fabricating the same.

As electronic products trend toward high speed and/or low power consumption, high speed and low operating voltages are increasingly required for semiconductor memory devices incorporated in the electronic products. In order to meet the requirements above, magnetic memory devices have been developed as semiconductor memory devices. Because magnetic memory devices operate at high speeds and have nonvolatile characteristics, the magnetic memory devices have attracted considerable attention as next-generation semiconductor memory devices.

In general, the magnetic memory device may include a magnetic tunnel junction pattern. The magnetic tunnel junction pattern includes two magnetic structures and an insulation layer interposed therebetween. The resistance of the magnetic tunnel junction pattern varies depending on magnetization directions of the two magnetic structures. For example, the magnetic tunnel junction pattern has high resistance when the magnetization directions of the two magnetic structures are antiparallel and low resistance when the magnetization directions of the two magnetic structures are parallel. The magnetic memory device may write and read data using the resistance difference between the high and low resistances of the magnetic tunnel junction.

With the remarkable advance in electronic industry, there is an increasing demand for high integration and/or low power consumption of magnetic memory devices, and in addition, many studies have been conducted to improve reliability of magnetic memory devices.

### SUMMARY

Some embodiments of the present inventive concepts provide a magnetic memory device with improved reliability and a method of fabricating the same.

According to some embodiments of the present inventive concepts, a magnetic memory device may comprise: a substrate, a conductive line on the substrate; a wiring dielectric layer that covers the conductive line; a lower shield line in the wiring dielectric layer, the lower shield line extending in a first direction; a data storage pattern that includes a bottom electrode, a magnetic tunnel junction pattern, and a top electrode that are sequentially stacked on the lower shield line; and an upper shield line on the data storage pattern, the upper shield line extending in a second direction parallel to a top surface of the substrate, the second direction intersecting the first direction. The lower shield line and the upper shield line may include a magnetic material.

According to some embodiments of the present inventive concepts, a magnetic memory device may comprise: a substrate, conductive lines on the substrate; a wiring dielectric layer that covers the conductive lines; lower shield lines that extend in a first direction in the wiring dielectric layer and each of the lower shield lines is spaced apart from each other in a second direction, the first and second directions being crossed with each other and parallel to a top surface of the substrate; data storage patterns on the lower shield lines and each of the data storage patterns spaced apart from each other in the first and second directions; and upper shield lines that extend in the second direction on the data storage patterns and each of the upper shield lines is spaced apart from each other in the first direction. The lower shield lines and the upper shield lines include a magnetic material.

According to some embodiments of the present inventive concepts, a magnetic memory device may comprise: a substrate, conductive lines on the substrate; a wiring dielectric layer that covers the conductive lines; lower shield lines that extend in a first direction in the wiring dielectric layer and each of the lower shield lines is spaced apart from each other in a second direction, the first and second directions being crossed with each other and parallel to a top surface of the substrate; data storage patterns on the lower shield lines and each of the data storage patterns spaced apart from each other in the first and second directions, each of the data storage patterns including a bottom electrode, a first magnetic pattern, a tunnel barrier pattern, a second magnetic pattern, and a top electrode that are sequentially stacked; and upper shield lines that extend in the second direction on the data storage patterns and each of the upper shield lines is are spaced apart from each other in the first direction. A bottom surface of each of the bottom electrodes may be in contact with a top surface of a corresponding one of the lower shield lines. A top surface of each of the top electrodes is in contact with a bottom surface of a corresponding one of the upper shield lines.

### BRIEF DESCRIPTION OF DRAWINGS

FIG. 1 illustrates a circuit diagram showing a unit memory cell of a magnetic memory device according to some embodiments of the present inventive concepts.

FIG. 2 illustrates a plan view showing a magnetic memory device according to some embodiments of the present inventive concepts.

FIGS. 3A, 4A, 5A, and 6A illustrate cross-sectional views taken along line A-A′ of FIG. 2.

FIGS. 3B, 4B, 5B, and 6B illustrate cross-sectional views taken along line B-B′ of FIG. 2.

FIG. 7 illustrates a cross-sectional view showing an example of a magnetic tunnel junction pattern in a magnetic memory device according to some embodiments of the present inventive concepts.

FIGS. 8A and 8B illustrate cross-sectional respectively views taken along lines A-A′ and B-B′ of FIG. 2, showing a method of fabricating a magnetic memory device according to some embodiments of the present inventive concepts.

FIGS. 9, 10, 11, 12, 13, and 14 illustrate cross-sectional views taken along line A-A′ of FIG. 2, showing a method of fabricating a magnetic memory device according to some embodiments of the present inventive concepts.

FIGS. 15A and 15B illustrate cross-sectional views taken along lines A-A′ and B-B′ of FIG. 2, showing a method of fabricating the magnetic memory device of FIGS. 3A and 3B.

### DETAILED DESCRIPTION OF EMBODIMENTS

The following will now describe in detail some embodiments of the present inventive concepts with reference to the accompanying drawings. The inventive concept may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

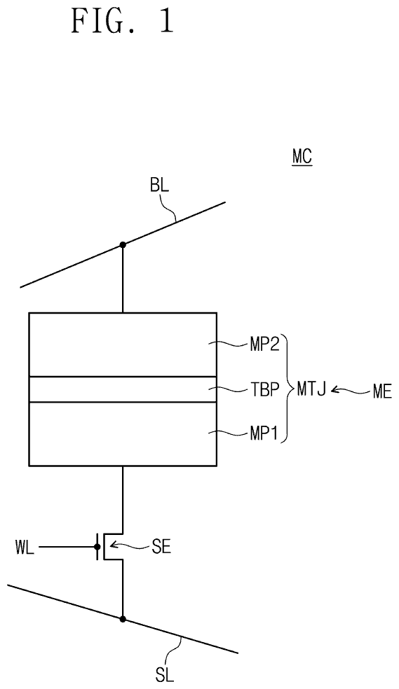

FIG. 1 illustrates a circuit diagram showing a unit memory cell of a magnetic memory device according to some embodiments of the present inventive concepts.

Referring to FIG. 1, a unit memory cell MC may include a memory element ME and a selection element SE. The memory element ME and the selection element SE may be electrically connected to each other in series. The memory element ME may be connected between the selection element SE and a bit line BL. The selection element SE may be connected between the memory element ME and a source line SL and may be controlled by a word line WL. The selection element SE may include, for example, a bipolar transistor or a metal oxide semiconductor (MOS) field effect transistor.

The memory element ME may include a magnetic tunnel junction pattern MTJ, and the magnetic tunnel junction pattern MTJ may include a first magnetic pattern MP1, a second magnetic pattern MP2, and a tunnel barrier pattern TBP between the first and second magnetic patterns MP1 and MP2. One of the first or second magnetic patterns MP1 or MP2 may be a reference magnetic pattern whose magnetization direction is fixed in one direction irrespective of external magnetic field under ordinary use environment. The other of the first and second magnetic patterns MP1 and MP2 may be a free magnetic pattern whose magnetization direction is changed due to an external magnetic field between two stable magnetization directions. The magnetic tunnel junction pattern MTJ may have an electrical resistance whose value is much greater in a case that the magnetization directions of the reference and free magnetic patterns are antiparallel to each other than in a case that the magnetization directions of the reference and free magnetic patterns are parallel to each other. For example, an electrical resistance of the magnetic tunnel junction pattern MTJ may be controlled by changing the magnetization direction of the free magnetic pattern. The memory element ME may use the difference in electrical resistance dependent on the magnetization directions of the reference and free magnetic patterns, which mechanism may cause the unit memory cell MC to store data therein.

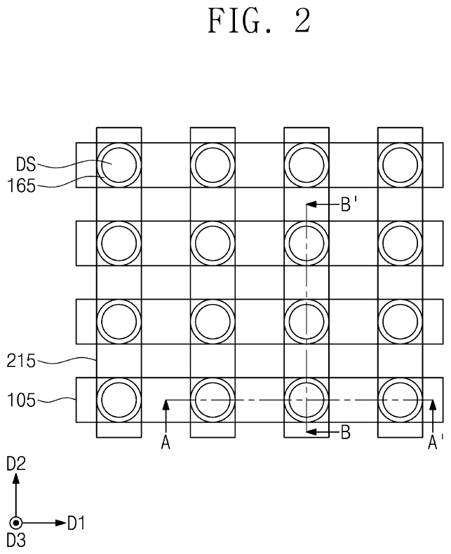

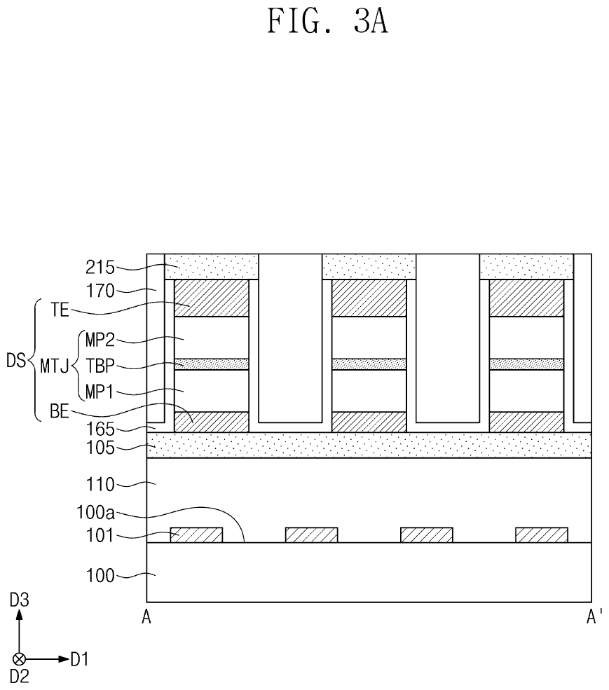

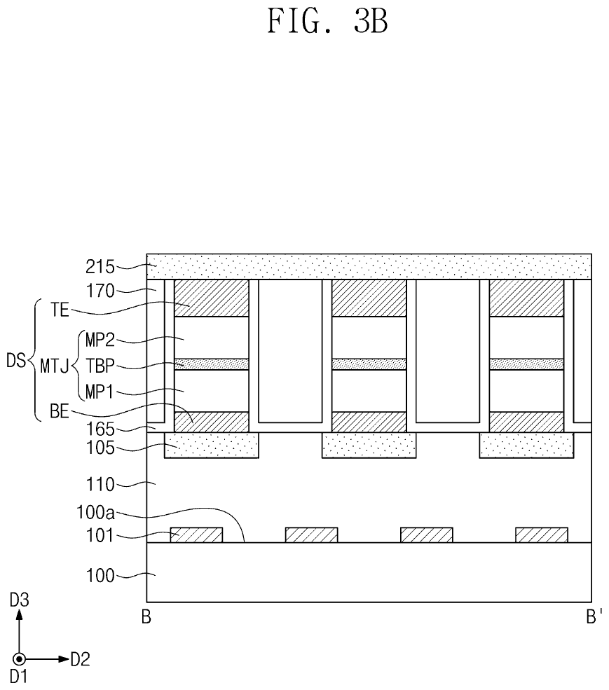

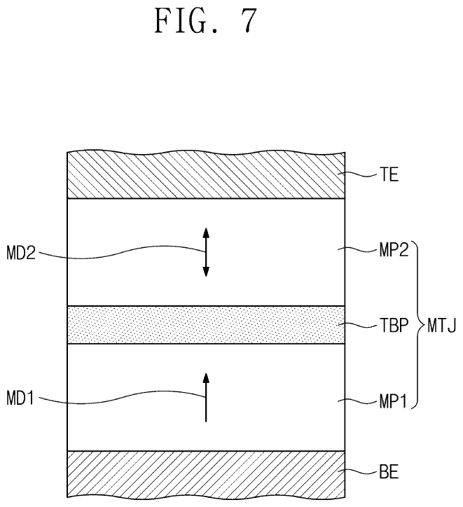

FIG. 2 illustrates a plan view showing a magnetic memory device according to some embodiments of the present inventive concepts. FIG. 3A illustrates a cross-sectional view taken along line A-A′ of FIG. 2. FIG. 3B illustrates a cross-sectional view taken along line B-B′ of FIG. 2. FIG. 7 illustrates a cross-sectional view showing an example of a magnetic tunnel junction pattern in a magnetic memory device according to some embodiments of the present inventive concepts.

Referring to FIGS. 2, 3A, and 3B, conductive lines 101 may be disposed on a substrate 100, and a wiring dielectric layer 110 may be disposed to cover the conductive lines 101. The substrate 100 may be a semiconductor substrate including silicon, silicon on insulator (SOI), silicon-germanium (SiGe), germanium (Ge), or gallium-arsenic (GaAs). The wiring dielectric layer 110 may include, for example, one or more of silicon oxide, silicon nitride, or silicon oxynitride.

Although not shown, a selection element (see SE of FIG. 1) may be disposed in the substrate 100. The selection element may include, for example, a field effect transistor. The conductive lines 101 may be electrically connected to one terminal (e.g., a source/drain terminal) of the selection element. The conductive lines 101 may include metal (e.g., copper).

Lower shield lines 105 may be disposed on the wiring dielectric layer 110. The lower shield lines 105 may extend in a first direction D1 and may be spaced apart from each other in a second direction D2. In this description, the first direction D1 and the second direction D2 may be directions that are parallel to a top surface 100a of the substrate 100 and cross over each other. A third direction D3 may be perpendicular to the top surface 100a of the substrate 100. In some examples, the first direction D1, the second direction D2, and the third direction D3 may be orthogonal to each other.

According to the embodiment of the present inventive concepts shown in FIGS. 3A and 3B, the lower shield lines 105 may be electrically connected to the conductive lines 101 through contacts (not shown) present in the wiring dielectric layer 110. For example, the lower shield lines 105 may serve as lower wiring lines.

Top surfaces of the lower shield lines 105 may be exposed from the wiring dielectric layer 110. The wiring dielectric layer 110 may have a top surface substantially coplanar with the top surfaces of the lower shield lines 105.

Data storage patterns DS may be disposed on the lower shield lines 105. The data storage patterns DS may be spaced apart from each other in the first direction D1 and the second direction D2. Each of the data storage patterns DS may have a bottom surface in contact with the top surface of a corresponding one of the lower shield lines 105. Each of the data storage patterns DS may be electrically connected to one terminal (e.g., a drain terminal) of a corresponding selection element through a corresponding lower shield line 105 and a corresponding conductive line 101. The lower shield lines 105 may each include a magnetic material. The magnetic material may be, for example, at least one magnetic material selected from cobalt (Co), iron (Fe), and nickel (Ni). According to some embodiments, the lower shield lines 105 may include a soft magnetic material.

Each of the data storage patterns DS may include a bottom electrode BE, a magnetic tunnel junction pattern MTJ, and a top electrode TE that are sequentially stacked on a corresponding lower shield line 105. The magnetic tunnel junction pattern MTJ may be interposed between the bottom electrode BE and the top electrode TE. Each of the bottom electrodes BE may have a bottom surface in contact with the top surface of a corresponding one of the lower shield lines 105. The bottom electrode BE may include, for example, conductive metal nitride (e.g., titanium nitride or tantalum nitride). The top electrode TE may include at least one material selected from a metal (e.g., Ta, W, Ru, or Ir) or a conductive metal nitride (e.g., TiN).

The magnetic tunnel junction pattern MTJ may include a first magnetic pattern MP1, a second magnetic pattern MP2, and a tunnel barrier pattern TBP between the first and second magnetic patterns MP1 and MP2. The first magnetic pattern MP1 may be disposed between the bottom electrode BE and the tunnel barrier pattern TBP, and the second magnetic pattern MP2 may be disposed between the top electrode TE and the tunnel barrier pattern TBP. The bottom electrode BE may include, for example, conductive metal nitride (e.g., titanium nitride or tantalum nitride). The top electrode TE may include at least one material selected from a metal (e.g., Ta, W, Ru, or Ir) or a conductive metal nitride (e.g., TiN).

Referring to FIG. 7, the first magnetic pattern MP1 may be a reference layer having a magnetization direction MD1 that is fixed in one direction, and the second magnetic pattern MP2 may be a free layer having a magnetization direction MD2 that is changed parallel or antiparallel to the magnetization direction MD1 of the first magnetic pattern MP1. FIG. 7 discloses that the second magnetic pattern MP2 is a free layer, but the present inventive concepts are not limited thereto. Differently from that shown in FIG. 7, the first magnetic pattern MP1 may be the free layer, and the second magnetic pattern MP2 may be a reference layer.

For example, the magnetization directions MD1 and MD2 of the first and second magnetic patterns MP1 and MP2 may be perpendicular to an interface between the tunnel barrier pattern TBP and the second magnetic pattern MP2. In this case, each of the first and second magnetic patterns MP1 and MP2 may include at least of an intrinsic perpendicular magnetic material or an extrinsic perpendicular magnetic material. The intrinsic perpendicular magnetic material may include a material having perpendicular magnetization properties found even in the absence of an external factor. The intrinsic perpendicular magnetic material may include at least one material selected from a perpendicular magnetic material (e.g., CoFeTb, CoFeGd, or CoFeDy), a perpendicular magnetic material having an L1₀ magnetic structure, CoPt of a hexagonal close packed lattice structure, or a perpendicular magnetic structure. The perpendicular magnetic material having the L1₀ magnetic structure may include at least one FePt of the L1₀ magnetic structure, FePd of the L1₀ magnetic structure, CoPd of the L1₀ magnetic structure, or CoPt of the L1₀ magnetic structure. The perpendicular magnetic structure may include magnetic layers and nonmagnetic layers that are alternately and repeatedly stacked. For example, the perpendicular magnetic structure may include at least of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n (where, n is the number of stacked layers). The extrinsic perpendicular magnetic material may include a material having intrinsic horizontal magnetization properties or perpendicular magnetization properties caused by an external factor. For example, the extrinsic perpendicular magnetic material may have perpendicular magnetization properties due to magnetic anisotropy induced by junction between the tunnel barrier pattern TBP and the first magnetic pattern MP1 (or the second magnetic pattern MP2). The extrinsic perpendicular magnetic material may include, for example, CoFeB.

The tunnel barrier pattern TBP may include at least one layer selected from a magnesium (Mg) oxide layer, a titanium (Ti) oxide layer, an aluminum (Al) oxide layer, a magnesium-zinc (MgZn) oxide layer, and a magnesium-boron (MgB) oxide layer.

Referring back to FIGS. 2, 3A, and 3B, a capping dielectric layer 165 may conformally cover a lateral surface of the bottom electrode BE, a lateral surface of the magnetic tunnel junction pattern MTJ, and a lateral surface of the top electrode TE. When viewed in a plan view, the capping dielectric layer 165 may surround the lateral surface of the bottom electrode BE, the lateral surface of the magnetic tunnel junction pattern MTJ, and the lateral surface of the top electrode TE. The capping dielectric layer 165 may include nitride (e.g., silicon nitride).

A cell dielectric layer 170 may be disposed on the wiring dielectric layer 110, covering the data storage patterns DS. The cell dielectric layer 170 may fill a space between the data storage patterns DS. The capping dielectric layer 165 may be interposed between the cell dielectric layer 170 and a lateral surface of each of the data storage patterns DS, and may extend between the wiring dielectric layer 110 and the cell dielectric layer 170. The cell dielectric layer 170 may include, for example, one or more of silicon oxide, silicon nitride, or silicon oxynitride.

Upper shield lines 215 may be disposed on the data storage patterns DS. The upper shield lines 215 may extend in the second direction D2 and may be spaced apart from each other in the first direction D1. Each of the data storage patterns DS may have a top surface in contact with a bottom surface of a corresponding one of the upper shield lines 215. For example, each of the top electrodes TE may have a top surface in contact with a bottom surface of a corresponding one of the upper shield lines 215. The upper shield lines 215 may include a magnetic material. The magnetic material may include, for example, at least one material selected from cobalt (Co), iron (Fe), or nickel (Ni). According to some embodiments, the upper shield lines 215 may include a soft magnetic material.

When viewed in a plan view, the lower shield lines 105 may intersect the upper shield lines 215. The data storage patterns DS may be disposed at intersections where the lower shield lines 105 vertically overlap the upper shield lines 215.

Since a magnetic memory device is characterized in that data is stored based on a magnetization direction, the magnetic memory device may be influenced by external magnetic fields. A magnetic memory device using perpendicular magnetization may have a problem of a reduction in reliability when there is a horizontal magnetic component in an external magnetic field.

According to the present inventive concepts, the lower and upper shield lines 105 and 215 may cause a reduction in magnetic flux of the horizontal component of the external magnetic field. Thus, the magnetic flux of the horizontal component that passes through the data storage pattern DS may be minimized to provide a magnetic memory device with improved electrical properties and increased reliability. In addition, as the lower and upper shield lines 105 and 215 approach the magnetic tunnel junction pattern MTJ, there may be a successful reduction in effect of an external magnetic field on the magnetic tunnel junction pattern MTJ. According to the embodiment of FIGS. 3A and 3B, the lower and upper shield lines 105 and 215 may be in contact with the bottom and top electrodes BE and TE. Therefore, the lower and upper shield lines 105 and 215 may be disposed near the magnetic tunnel junction pattern MTJ, it may be possible to minimize the effect of an external magnetic field on the magnetic tunnel junction pattern MTJ. Furthermore, in this case, the lower and upper shield lines 105 and 215 may share a function of electric wires, and a method of fabricating a magnetic memory device may become simplified.

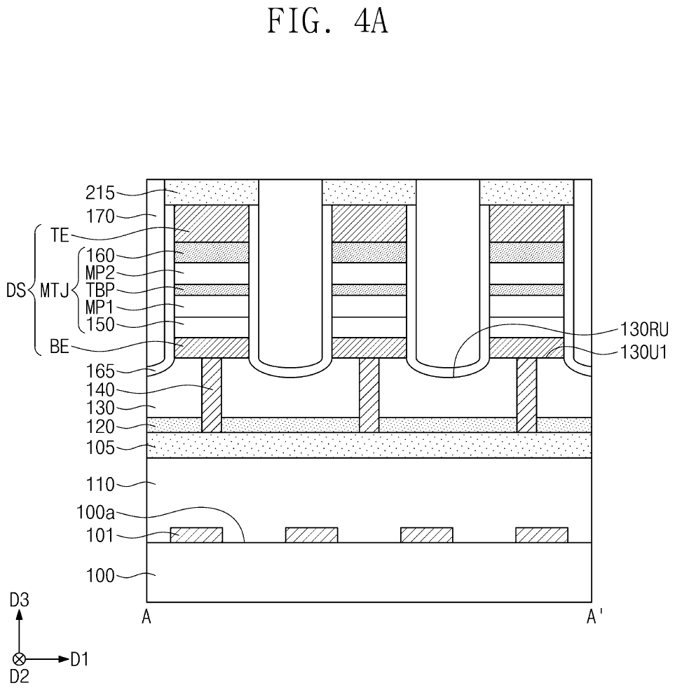

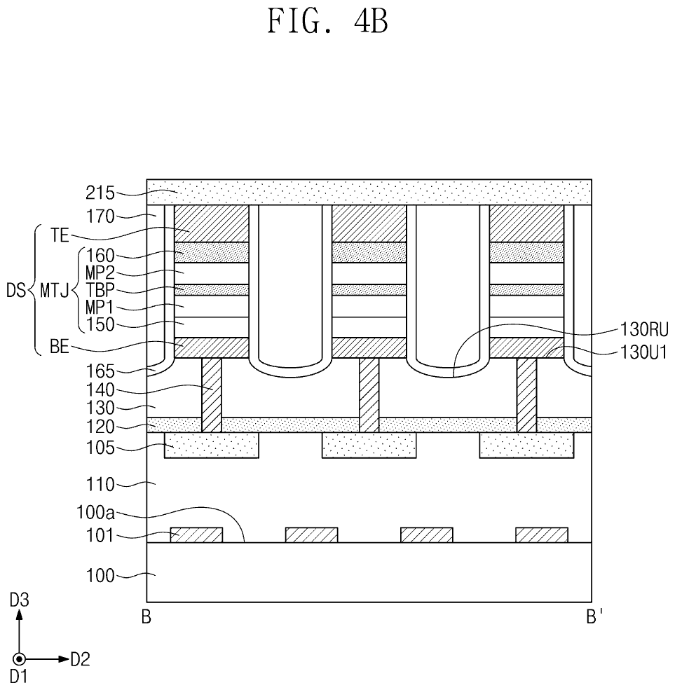

FIG. 4A illustrates a cross-sectional view taken along line A-A′ of FIG. 2. FIG. 4B illustrates a cross-sectional view taken along line B-B′ of FIG. 2. For brevity of description, a duplicate explanation of elements that were described previously may be omitted.

Referring to FIGS. 2, 4A, and 4B, a first lower dielectric layer 120 and a second lower dielectric layer 130 may be sequentially disposed on a wiring dielectric layer 110. The first lower dielectric layer 120 may cover exposed top surfaces of lower shield lines 105. The first and second lower dielectric layers 120 and 130 may include, for example, one or more of silicon oxide, silicon nitride, or silicon oxynitride. According to some embodiments, the second lower dielectric layer 130 may include a different material from that of the first lower dielectric layer 120. For example, the first lower dielectric layer 120 may include silicon nitride (e.g., SiCN), and the second lower dielectric layer 130 may include silicon oxide (e.g., tetraethoxysilane (TEOS)).

Data storage patterns DS may be disposed on the second lower dielectric layer 130. The data storage patterns DS may be spaced apart from each other in first and second directions D1 and D2.

The second lower dielectric layer 130 may have a top surface 130RU that is recessed toward the substrate 100 between the data storage patterns DS. The recessed top surface 130RU of the second lower dielectric layer 130 may be located at a height lower than that of an uppermost surface 130U1 of the second lower dielectric layer 130. In this description, the term “height” may indicate a distance measured in a third direction D3.

Lower electrode contacts 140 may be disposed in the first and second lower dielectric layers 120 and 130. The lower electrode contacts 140 may be correspondingly disposed beneath and electrically connected to the data storage patterns DS. The lower electrode contacts 140 may penetrate the first and second lower dielectric layers 120 and 130. Each of the lower electrode contacts 140 may be connected to a corresponding one of the lower shield lines 105. Each of the data storage patterns DS may be electrically connected to one end (e.g., a drain terminal) of a corresponding selection element through a corresponding lower electrode contact 140 and a corresponding lower shield line 105.

The lower electrode contacts 140 may include at least one material selected from doped semiconductors (e.g., doped silicon), metals (e.g., tungsten, titanium, or tantalum), metal-semiconductor compounds (e.g., metal silicide), or conductive metal nitrides (e.g., titanium nitride, tantalum nitride, or tungsten nitride).

Each of the data storage patterns DS may include a bottom electrode BE, a magnetic tunnel junction pattern MTJ, and a top electrode TE that are sequentially stacked in the third direction D3 on the second lower dielectric layer 130. The magnetic tunnel junction pattern MTJ may be interposed between the bottom electrode BE and the top electrode TE. Each of the lower electrode contacts 140 may be electrically connected to the bottom electrode BE of one of the data storage patterns DS. The bottom electrode BE of each of the data storage patterns DS may be in contact with a top surface of each of the lower electrode contacts 140 and with an uppermost surface 130U1 of the second lower dielectric layer 130.

The magnetic tunnel junction pattern MTJ may include a first magnetic pattern MP1, a second magnetic pattern MP2, and a tunnel barrier pattern TBP between the first and second magnetic patterns MP1 and MP2. The first magnetic pattern MP1 may be disposed between the bottom electrode BE and the tunnel barrier pattern TBP, and the second magnetic pattern MP2 may be disposed between the top electrode TE and the tunnel barrier pattern TBP.

The magnetic tunnel junction pattern MTJ may further include a seed pattern 150 between the bottom electrode BE and the first magnetic pattern MP1. At least a portion of the seed pattern 150 may be amorphous. As at least a portion of the seed pattern 150 has an amorphous phase, crystallinity of the bottom electrode BE underneath the seed pattern 150 may be prevented from transferring into the first magnetic pattern MP1, thereby facilitating growth of the first magnetic pattern MP1. The seed pattern 150 may include a non-magnetic metal element. The seed pattern 150 may include, for example, one or more of tantalum nitride (TaN) or tantalum (Ta).

The magnetic tunnel junction pattern MTJ may further include a capping pattern 160 between the top electrode TE and the second magnetic pattern MP2. The capping pattern 160 may prevent degradation of the second magnetic pattern MP2. The capping pattern 160 may include, for example, at least one material selected from tantalum (Ta), ruthenium (Ru), molybdenum (Mo), aluminum (Al), copper (Cu), silver (Ag), titanium (Ti), tantalum nitride (TaN), or titanium nitride (TiN).

A capping dielectric layer 165 may conformally cover a lateral surface of each of the data storage patterns DS. The capping dielectric layer 165 may be interposed between a cell dielectric layer 170 and the lateral surface of each of the data storage patterns DS, and may extend between the cell dielectric layer 170 and a recessed top surface 130RU of the second lower dielectric layer 130.

According to the embodiment of the present inventive concepts as shown in FIGS. 4A and 4B, lower and upper shield lines 105 and 215 may share a function of electric wires, and a method of fabricating a magnetic memory device may become simplified.

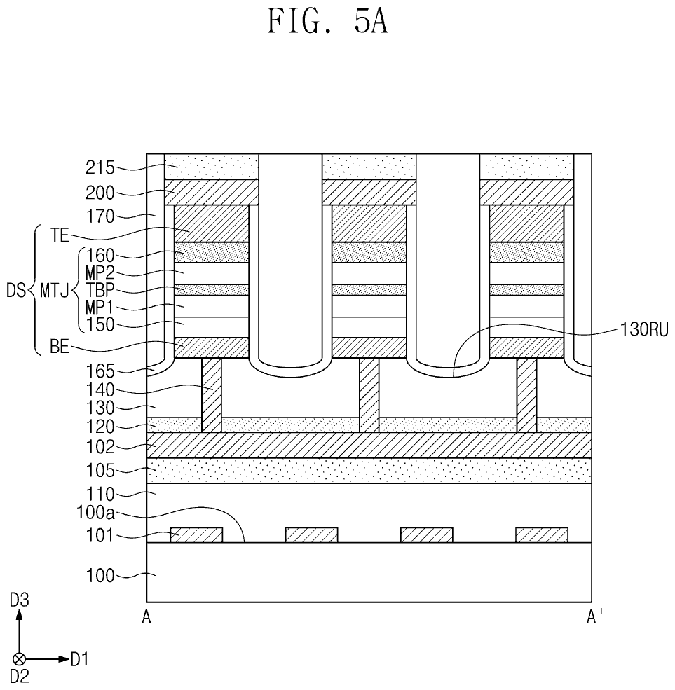

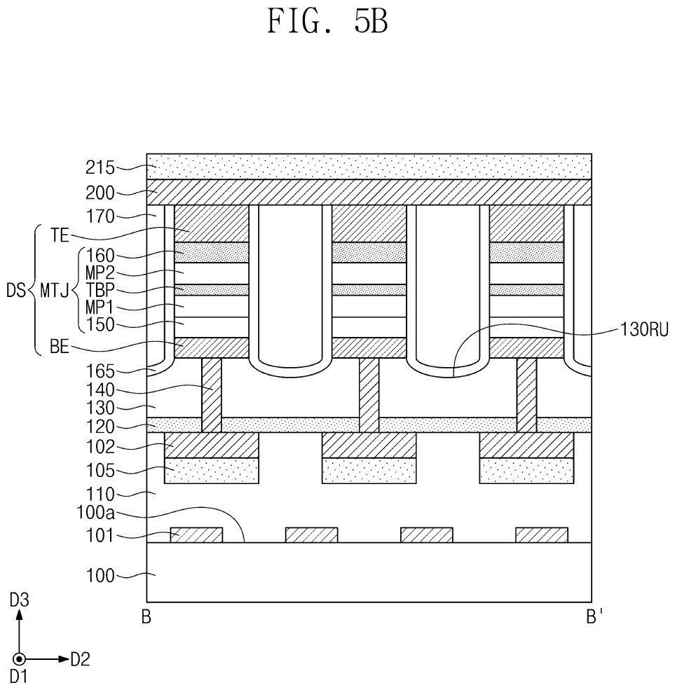

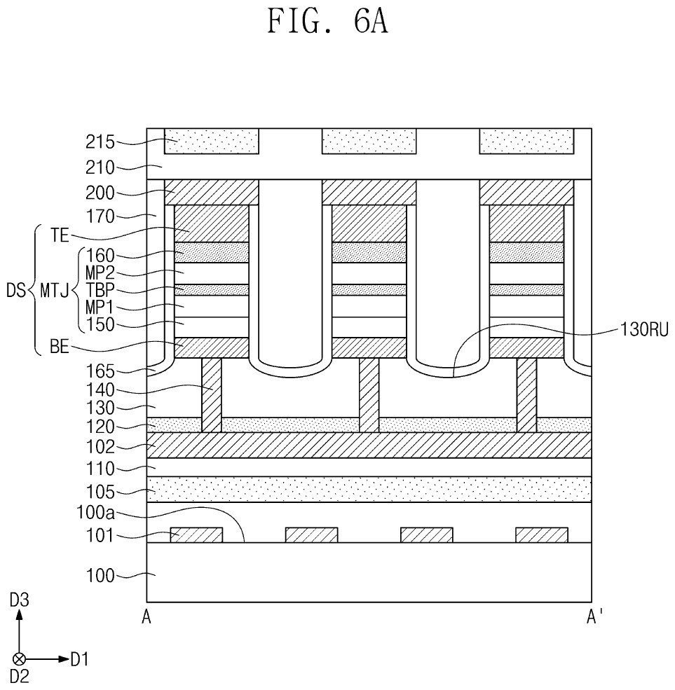

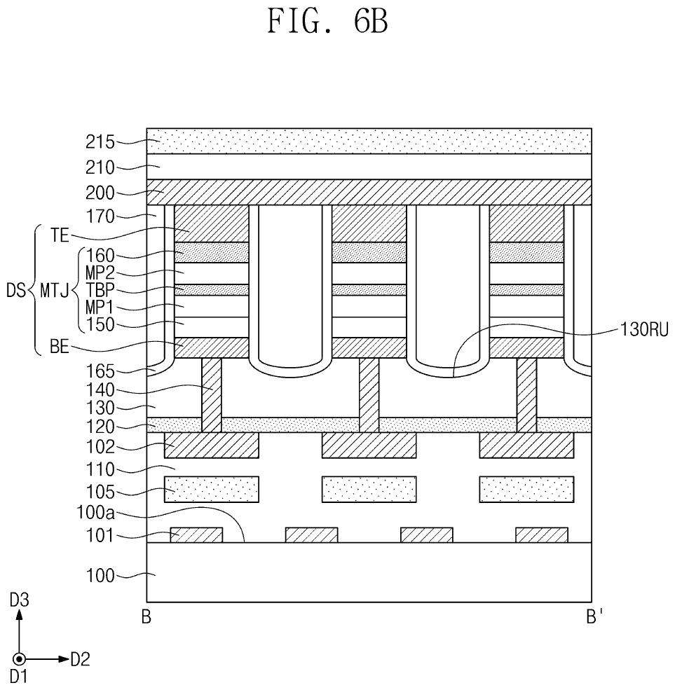

FIGS. 5A and 6A illustrate cross-sectional views taken along line A-A′ of FIG. 2. FIGS. 5B and 6B illustrate cross-sectional views taken along line B-B′ of FIG. 2. For brevity of description, a duplicate explanation of items described previously may be omitted.

Referring to FIGS. 2, 5A, and 5B, lower wiring lines 102 may be disposed between a first lower dielectric layer 120 and lower shield lines 105. The lower wiring lines 102 may be correspondingly interposed between lower electrode contacts 140 and the lower shield lines 105. The lower wiring lines 102 may be disposed in a wiring dielectric layer 110. The lower wiring lines 102 may extend in a first direction D1 and be spaced apart from each other in a second direction D2. The wiring dielectric layer 110 may expose top surfaces of the lower wiring lines 102. The wiring dielectric layer 110 may have a top surface substantially coplanar with the top surfaces of the lower wiring lines 102. The first lower dielectric layer 120 may be disposed on the wiring dielectric layer 110, and may cover the exposed top surfaces of the lower wiring lines 102. The lower wiring lines 102 may be electrically connected to conductive lines 101 through contacts (not shown) present in the wiring dielectric layer 110.

Each of the lower electrode contacts 140 may penetrate through the first and second lower dielectric layers 120 and 130 to come into electrical connection with a corresponding one of the lower wiring lines 102. Each of data storage patterns DS may be electrically connected to one end (e.g., a drain terminal) of a corresponding selection element through one of the lower electrode contacts 140, a corresponding lower wiring line 102, and a corresponding conductive line 101.

Each of the lower shield lines 105 may be in contact with a bottom surface of a corresponding one of the lower wiring lines 102. When viewed in plan, each of the lower shield lines 105 may vertically overlap a corresponding one of the lower wiring lines 102.

Upper wiring lines 200 may be interposed between upper shield lines 215 and the data storage patterns DS. The upper wiring lines 200 may extend in a second direction D2 and may be spaced apart from each other in a first direction D1. The upper wiring lines 200 may be disposed in a cell dielectric layer 170. Each of the data storage patterns DS may be electrically connected to a corresponding one of the upper wiring lines 200. Each of the upper shield lines 215 may have a bottom surface in contact with a top surface of a corresponding one of the upper wiring lines 200. When viewed in plan, each of the upper shield lines 215 may vertically overlap a corresponding one of the upper wiring lines 200.

The lower wiring lines 102 and the upper wiring lines 200 may include, for example, copper.

Referring to FIGS. 2, 6A, and 6B, lower wiring lines 102 and lower shield lines 105 may be spaced apart from each other in a direction (e.g., a third direction D3) perpendicular to a top surface 100a of a substrate 100. A wiring dielectric layer 110 may be provided therein with the lower wiring lines 102 and the lower shield lines 105 that are spaced apart from each other across a portion of the wiring dielectric layer 110. When viewed in plan, each of the lower shield lines 105 may vertically overlap a corresponding one of the lower wiring lines 102.

A cell dielectric layer 170 may expose top surfaces of upper wiring lines 200. The cell dielectric layer 170 may have a top surface substantially coplanar with those of the upper wiring lines 200. An upper dielectric layer 210 may be disposed on the cell dielectric layer 170. The upper dielectric layer 210 may cover the exposed top surfaces of the upper wiring lines 200. The upper dielectric layer 210 may include, for example, one or more of silicon oxide, silicon nitride, or silicon oxynitride.

Upper shield lines 215 may be disposed in the upper dielectric layer 210. The upper shield lines 215 may extend in a second direction D2 and may be spaced apart from each other in a first direction D1. The upper shield lines 215 may be spaced apart in a vertical direction (e.g., a third direction D3) from the upper wiring lines 200. The upper dielectric layer 210 may be interposed between the upper wiring lines 200 and the upper shield lines 215. The upper wiring lines 200 and the upper shield lines 215 may be spaced apart from each other across a portion of the upper dielectric layer 210. When viewed in plan, each of the upper shield lines 215 may vertically overlap a corresponding one of the upper wiring lines 200. According to some embodiments, compared with the upper shield lines 215, the upper wiring lines 200 may be elongated in the second direction D2.

A magnetic memory device of FIGS. 5A and 5B may further include the lower wiring lines 102 and the upper wiring lines 200 that serve as electric wires. The lower and upper shield lines 105 and 215 may be in contact with, without being insulated from, corresponding lower and upper wiring lines 102 and 200. In this case, compared with the embodiment of FIGS. 6A and 6B, a reduced distance may be provided between the magnetic tunnel junction pattern MTJ and the lower and upper shield lines 105 and 215. Thus, there may be a successful reduction in effect of an external magnetic field on the magnetic tunnel junction pattern MTJ, and the magnetic memory device may increase in reliability.

In a magnetic memory device of FIGS. 6A and 6B, the lower wiring lines 102 may be spaced apart and insulated from the lower shield lines 105. The upper wiring lines 200 may be spaced apart and insulated from the upper shield lines 215. In this case, the lower and upper shield lines 105 and 215 may only cause a reduction in magnetic flux of a horizontal component of an external magnetic field. As the lower and upper wiring lines 102 and 200 include their materials more suitable for electric wires and serve as electric wires, the magnetic memory device may improve in electrical properties.

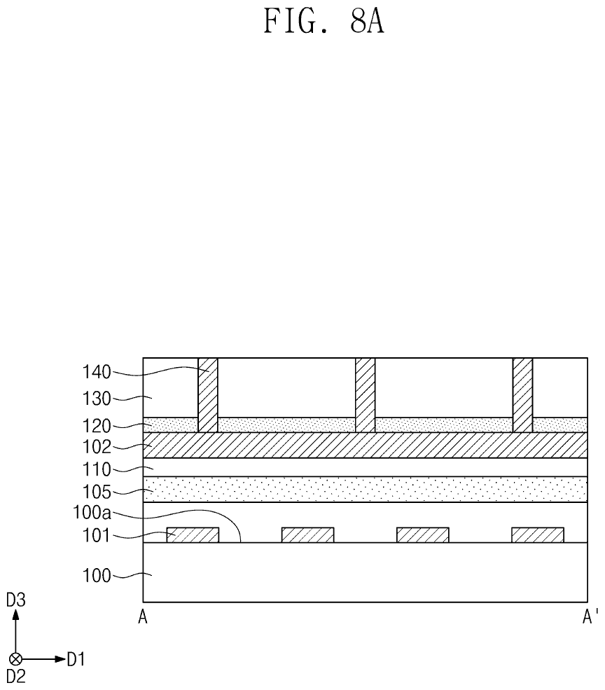

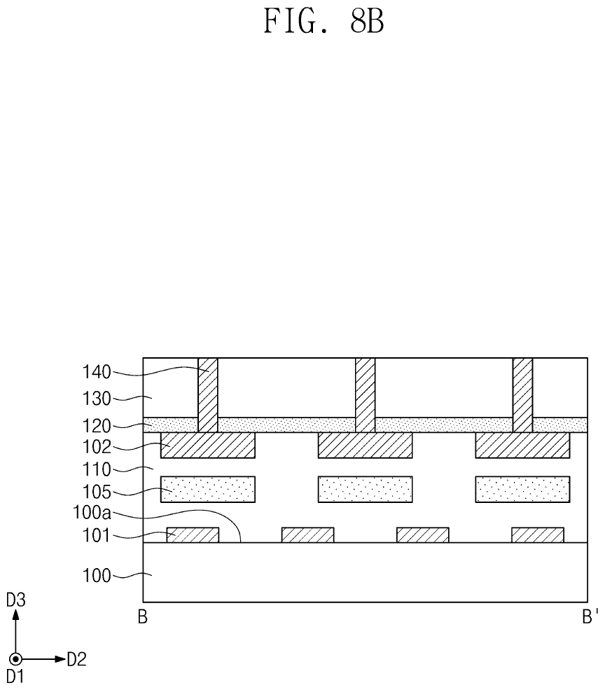

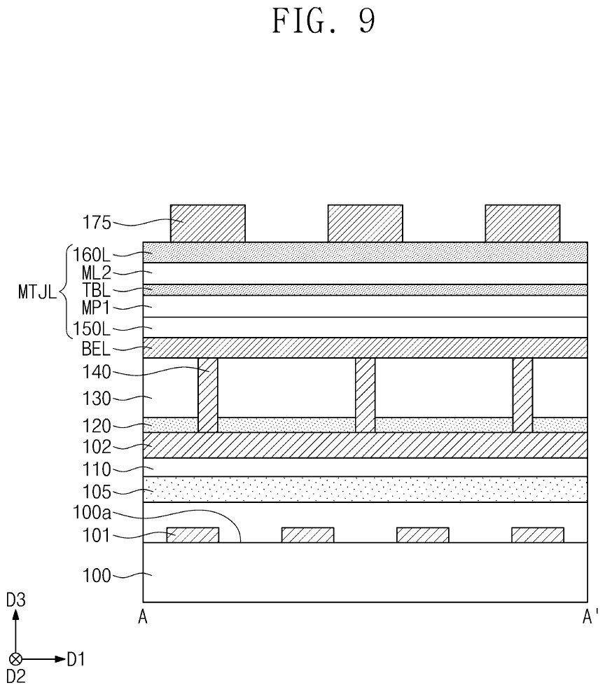

FIGS. 8A and 8B illustrate cross-sectional respectively views taken along lines A-A′ and B-B′ of FIG. 2, showing a method of fabricating a magnetic memory device according to some embodiments of the present inventive concepts. FIGS. 9 to 14 illustrate cross-sectional views taken along line A-A′ of FIG. 2, showing a method of fabricating a magnetic memory device according to some embodiments of the present inventive concepts. For brevity of description, duplicate descriptions of elements described previously may be omitted.

Referring to FIGS. 8A and 8B, a substrate 100 may be provided. Selection elements (see SE of FIG. 1) may be formed on the substrate 100. Conductive lines 101 may be formed on the substrate 100. The conductive lines 101 may be electrically connected to one terminal (e.g., a source/drain terminal) of the selection element.

A wiring dielectric layer 110 may be formed on the substrate 100. The wiring dielectric layer 110 may cover the conductive lines 101. Differently from that shown, the wiring dielectric layer 110 may include multiple layers.

Lower shield lines 105 may be formed in the wiring dielectric layer 110. The lower shield lines 105 may be formed spaced apart in a vertical direction (e.g., a third direction D3) from the conductive lines 101.

According to some embodiments, lower wiring lines 102 may be formed in the wiring dielectric layer 110. The wiring dielectric layer 110 may expose top surfaces of the lower wiring lines 102. The top surfaces of the lower wiring lines 102 may be coplanar with that of the wiring dielectric layer 110. According to some embodiments, as discussed with reference to FIGS. 5A and 5B, the lower wiring lines 102 may be formed to contact the lower shield lines 105. According to some embodiments, as discussed with reference to FIGS. 6A and 6B, the lower wiring lines 102 may be formed spaced apart vertically (e.g., in the third direction D3) from the lower shield lines 105. Contacts (not shown) may be formed in the wiring dielectric layer 110. The lower wiring lines 102 may be connected through the contacts (not shown) to the conductive lines 101.

According to some embodiments, as discussed with reference to FIGS. 4A and 4B, the formation of the lower wiring lines 102 may be omitted. In this case, the wiring dielectric layer 110 may expose top surfaces of the lower shield lines 105, and the top surfaces of the lower shield lines 105 may be coplanar with that of the wiring dielectric layer 110.

A first lower dielectric layer 120 and a second lower dielectric layer 130 may be sequentially formed on the wiring dielectric layer 110. A plurality of lower electrode contacts 140 may be formed in the first and second lower dielectric layers 120 and 130. According to some embodiments, the lower electrode contacts 140 may penetrate through the first and second lower dielectric layers 120 and 130, and may be connected to a corresponding one of the lower wiring lines 102. According to some embodiments, the lower electrode contacts 140 may penetrate through the first and second lower dielectric layers 120 and 130, and may be connected to a corresponding one of the lower shield lines 105.

The formation of the lower electrode contacts 140 may include, for example, forming lower contact holes (not shown) that penetrate through the first and second lower dielectric layers 120 and 130, forming a lower contact layer (not shown) that fills the lower contact holes, and planarizing the lower contact layer until a top surface of the second lower dielectric layer 130 is exposed. The planarization process may include, for example, a chemical mechanical polishing (CMP) process or an etch-back process.

Referring to FIG. 9, a bottom electrode layer BEL and a magnetic tunnel junction layer MTJL may be sequentially formed on the second lower dielectric layer 130. According to some embodiments, the magnetic tunnel junction layer MTJL may include a seed layer 150L, a first magnetic layer ML1, a tunnel barrier layer TBL, and a second magnetic layer ML2, and a capping layer 160L that are sequentially stacked on the bottom electrode layer BEL. The bottom electrode layer BEL and the magnetic tunnel junction layer MTJL may be formed by, for example, sputtering, chemical vapor deposition, or atomic layer deposition.

Conductive mask patterns 175 may be formed on the magnetic tunnel junction layer MTJL. The conductive mask patterns 175 may define regions on which magnetic tunnel junction patterns will be formed as discussed below. The conductive mask patterns 175 may include at least one of a metal (e.g., Ta, W, Ru, or Ir) or a conductive metal nitride (e.g., TiN).

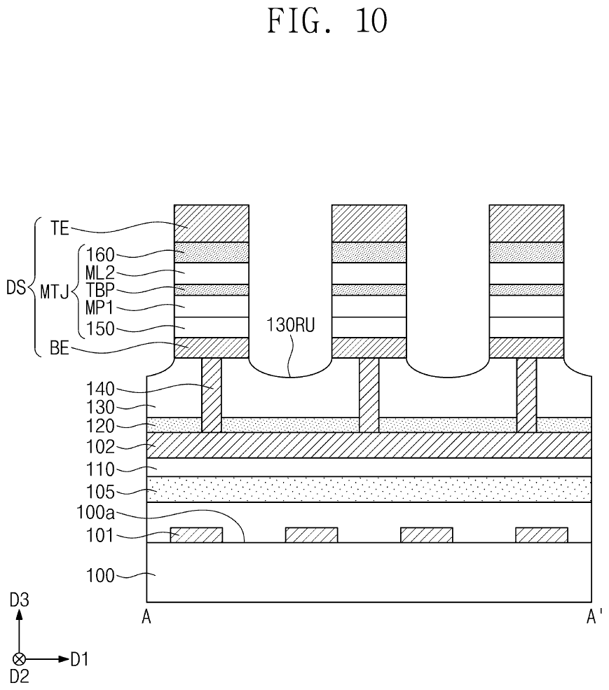

Referring to FIG. 10, the conductive mask patterns 175 may be used as an etching mask to sequentially etch the magnetic tunnel junction layer MTJL and the bottom electrode layer BEL. Therefore, a magnetic tunnel junction pattern MTJ and a bottom electrode BE may be formed on the second lower dielectric layer 130. The bottom electrode BE may be connected to a corresponding lower electrode contact 140, and the magnetic tunnel junction pattern MTJ may be formed on the bottom electrode BE.

The etching of the magnetic tunnel junction layer MTJL may include using the conductive mask patterns 175 as an etching mask to sequentially etch the capping layer 160L, the second magnetic layer ML2, the tunnel barrier layer TBL, the first magnetic layer ML1, and the seed layer 150L. Thus, the magnetic tunnel junction pattern MTJ may include a seed pattern 150, a first magnetic pattern MP1, a tunnel barrier pattern TBP, a second magnetic pattern MP2, and a capping pattern 160 that are sequentially stacked on the bottom electrode BE.

For example, an ion beam etching process using an ion beam may be employed as the etching process that etches the magnetic tunnel junction layer MTJL and the bottom electrode layer BEL. The ion beam may include inert ions. The ion beam etching process may recess the top surface of the second lower dielectric layer 130 on opposite sides of the magnetic tunnel junction pattern MTJ. Therefore, the second lower dielectric layer 130 may have a recessed top surface 130RU on opposite sides of the magnetic tunnel junction pattern MTJ. For example, the second lower dielectric layer 130 may have the recessed top surface 130RU between a plurality of magnetic tunnel junction patterns MTJ that are spaced apart from each other in first and second directions D1 and D2.

After the ion beam etching process, a residue of each of the conductive mask patterns 175 may remain on the magnetic tunnel junction pattern MTJ. The residue of each of the conductive mask patterns 175 may serve as a top electrode TE. In the following description, the residue of each of the conductive mask patterns 175 may be called the top electrode TE. The top electrode TE, the magnetic tunnel junction pattern MTJ, and the bottom electrode BE may constitute a data storage pattern DS.

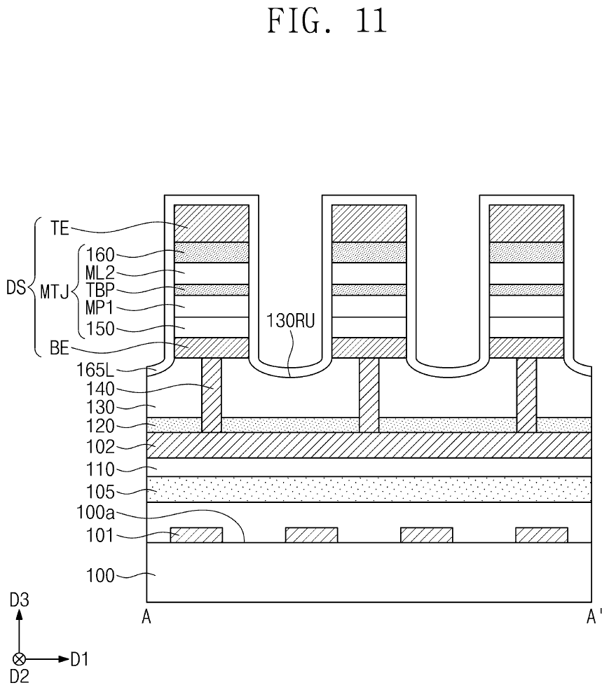

Referring to FIG. 11, a preliminary capping dielectric layer 165L may be formed to conformally cover top and lateral surfaces of each of the data storage patterns DS. The preliminary capping dielectric layer 165L may extend onto the recessed top surface 130RU of the second lower dielectric layer 130. The preliminary capping dielectric layer 165L may conformally cover the recessed top surface 130RU of the second lower dielectric layer 130. The formation of the preliminary capping dielectric layer 165L may include using a layer formation technique whose step coverage is excellent, such as atomic layer deposition (ALD).

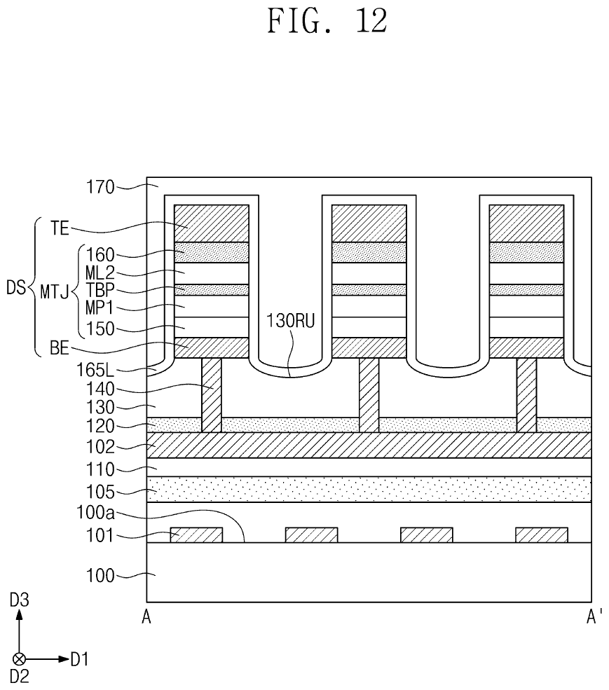

Referring to FIG. 12, a cell dielectric layer 170 may be formed on the preliminary capping dielectric layer 165L. The cell dielectric layer 170 may be formed on the preliminary capping dielectric layer 165L to cover the data storage patterns DS and to fill a space between the data storage patterns DS. The cell dielectric layer 170 may be formed by using, for example, a high density plasma chemical vapor deposition (HDP CVD) process.

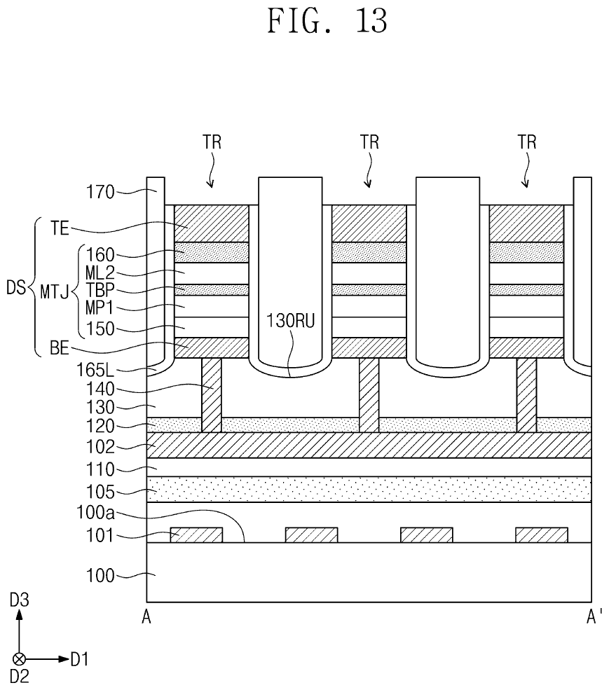

Referring to FIG. 13, an upper portion of each of the cell dielectric layer 170 and the preliminary capping dielectric layer 165L may be partially etched to form trenches TR. The upper portion of the preliminary capping dielectric layer 165L may be partially etched to form a capping dielectric layer 165. The trenches TR may extend in the second direction D2 and may be spaced apart from each other in the first direction D1. Each of the trenches TR may have a linear shape that extends in the second direction D2, and may expose corresponding data storage patterns DS that are spaced apart from each other in the second direction D2. Each of the trenches TR may expose the top electrode TE of a corresponding data storage pattern DS.

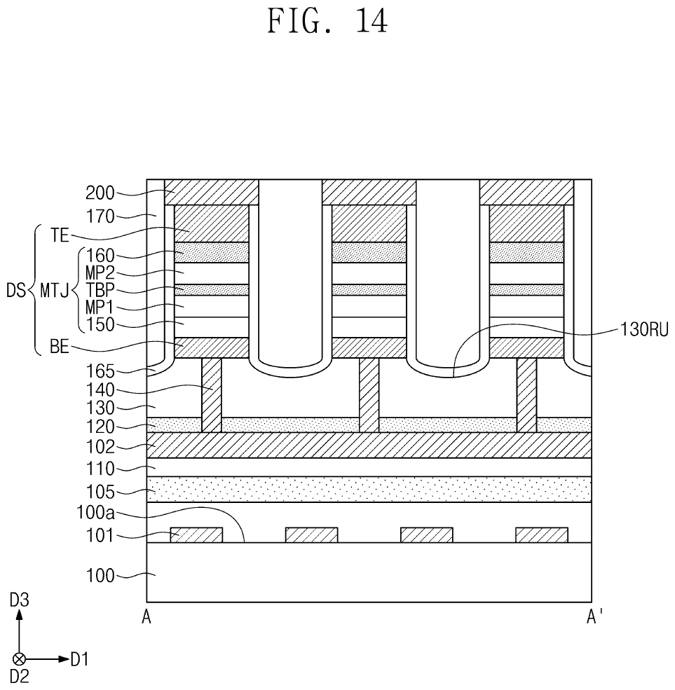

Referring to FIG. 14, upper wiring lines 200 may be formed in the trenches TR. The formation of the upper wiring lines 200 may include, for example, forming a conductive layer that fills the trenches TR, and planarizing the conductive layer until a top surface of the cell dielectric layer 170 is exposed. The planarization process may cause the top surface of the cell dielectric layer 170 to be coplanar with those of the upper wiring lines 200.

According to some embodiments, as discussed with reference to FIGS. 4A and 4B, the formation of the upper wiring lines 200 may be omitted. In this case, upper shield lines 215 may be formed in the trenches TR.

According to some embodiments, referring back to FIGS. 5A and 5B, the upper shield lines 215 may be formed on the upper wiring lines 200. Each of the upper shield lines 215 may have a bottom surface in contact with the top surface of a corresponding one of the upper wiring lines 200. When viewed in plan, each of the upper shield lines 215 may vertically overlap a corresponding one of the upper wiring lines 200.

According to some embodiments, referring back to FIGS. 6A and 6B, an upper dielectric layer 210 may be formed on the cell dielectric layer 170. The upper dielectric layer 210 may cover the upper wiring lines 200. Upper shield lines 215 may be formed in the upper dielectric layer 210. The upper shield lines 215 may be formed spaced apart in a vertical direction (e.g., the third direction D3) from the upper wiring lines 200 across a portion of the upper dielectric layer 210. Each of the upper shield lines 215 may vertically overlap a corresponding one of the upper wiring lines 200. A length in the second direction D2 of the upper shield lines 215 may be less than a length in the second direction D2 of the upper wiring lines 200.

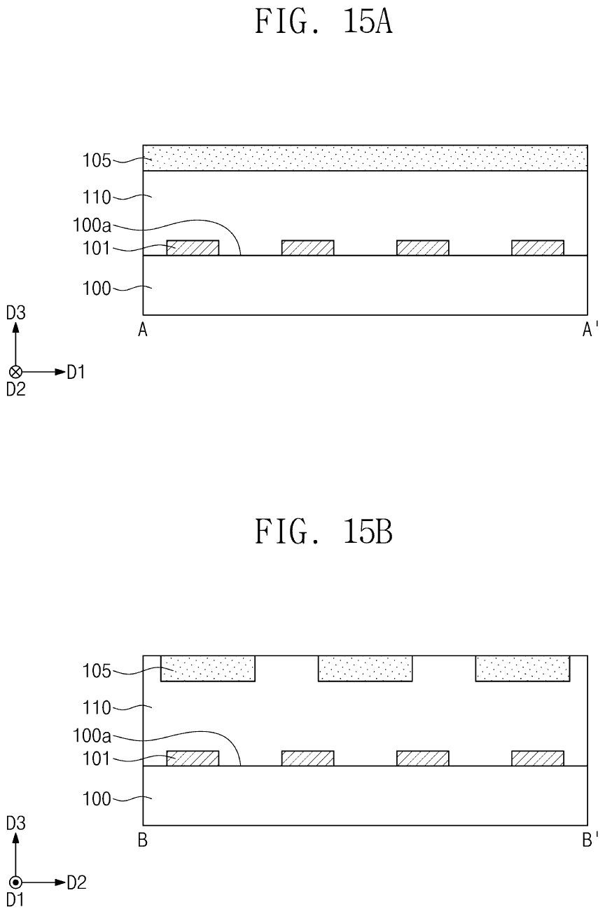

FIGS. 15A and 15B illustrate cross-sectional views taken along lines A-A′ and B-B′ of FIG. 2, showing a method of fabricating the magnetic memory device of FIGS. 3A and 3B. For brevity of description, a duplicate explanation will be omitted.

Referring to FIGS. 15A and 15B, a substrate 100 may be provided. Selection elements (see SE of FIG. 1) may be formed on the substrate 100. Conductive lines 101 may be formed on the substrate 100. The conductive lines 101 may be electrically connected to one terminal (e.g., a source/drain terminal) of the selection element.

A wiring dielectric layer 110 may be formed on the substrate 100. The wiring dielectric layer 110 may cover the conductive lines 101. Differently from that shown, the wiring dielectric layer 110 may include multiple layers.

Lower shield lines 105 may be formed in the wiring dielectric layer 110. The lower shield lines 105 may be formed spaced apart in a vertical direction (e.g., the third direction D3) from the conductive lines 101. The wiring dielectric layer 110 may expose top surfaces of the lower shield lines 105. The top surfaces of the lower shield lines 105 may be coplanar with that of the wiring dielectric layer 110. The lower shield lines 105 may extend in the first direction D1 and may be spaced apart from each other in the second direction D2.

Referring back to FIGS. 3A and 3B, there may be formed data storage patterns DS, a capping dielectric layer 165, a cell dielectric layer 170, and upper shield lines 215. The formation of the data storage patterns DS, the capping dielectric layer 165, and the cell dielectric layer 170 may be substantially the same as that discussed with reference to FIGS. 9 to 14. However, the formation of the upper wiring lines 200 may be omitted, and the upper shield lines 215 may be formed in the trenches TR.

According to the present inventive concepts, shield lines extending in the first and second directions may be present on top and bottom ends of a data storage pattern. The shield lines may reduce a magnetic flux of a horizontal component of an external magnetic field in a magnetic memory device that uses perpendicular polarization. Therefore, the magnetic memory device may increase in reliability.

Although the present invention has been described in connection with some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A magnetic memory device, comprising:
a substrate;
a conductive line on the substrate;
a wiring dielectric layer that covers the conductive line;
a lower shield line in the wiring dielectric layer, the lower shield line extending in a first direction;
a data storage pattern that includes a bottom electrode, a magnetic tunnel junction pattern, and a top electrode that are sequentially stacked on the lower shield line; and
an upper shield line on the data storage pattern, the upper shield line extending in a second direction parallel to a top surface of the substrate, the second direction intersecting the first direction,
wherein the lower shield line and the upper shield line include a magnetic material.

2. The device of claim 1, wherein the lower shield line and the upper shield line include at least one of cobalt (Co), iron (Fe), or nickel (Ni).

3. The device of claim 1, wherein
a bottom surface of the bottom electrode is in contact with a top surface of the lower shield line, and
a top surface of the top electrode is in contact with a bottom surface of the upper shield line.

4. The device of claim 1, wherein the magnetic tunnel junction pattern includes a seed pattern, a first magnetic pattern, a tunnel barrier pattern, a second magnetic pattern, and a capping pattern that are sequentially stacked on the bottom electrode.

5. The device of claim 1, further comprising:
a lower dielectric layer between the data storage pattern and the wiring dielectric layer; and
a lower electrode contact in the lower dielectric layer and electrically connected to the data storage pattern, the lower electrode contact penetrating through the lower dielectric layer.

6. The device of claim 5, wherein
a top surface of the top electrode is in contact with a bottom surface of the upper shield line, and
the lower electrode contact is electrically connected to the lower shield line.

7. The device of claim 6, wherein the lower dielectric layer has a recessed top surface that is recessed toward the substrate in a region where the lower dielectric layer does not vertically overlap the data storage pattern.

8. The device of claim 7, further comprising a capping dielectric layer that surrounds a lateral surface of the data storage pattern, the capping dielectric layer extending onto the recessed top surface of the lower dielectric layer.

9. The device of claim 5, further comprising:
a lower wiring line between the lower electrode contact and the lower shield line, the lower wiring line extending in the first direction; and
an upper wiring line between the upper shield line and the data storage pattern, the upper wiring line extending in the second direction,
wherein the lower electrode contact is electrically connected to the lower wiring line, and
wherein the data storage pattern is electrically connected to the upper wiring line.

10. The device of claim 9, wherein
the lower wiring line is in contact with the lower shield line, and
the upper wiring line is in contact with the upper shield line.

11. The device of claim 9, further comprising an upper dielectric layer between the upper wiring line and the upper shield line,
wherein the lower wiring line and the lower shield line are vertically spaced apart from each other across a portion of the wiring dielectric layer.

12. A magnetic memory device, comprising:
a substrate;
conductive lines on the substrate;
a wiring dielectric layer that covers the conductive lines;
lower shield lines that extend in a first direction in the wiring dielectric layer and each of the lower shield lines is spaced apart from each other in a second direction, the first and second directions being crossed with each other and parallel to a top surface of the substrate;
data storage patterns disposed on the lower shield lines and each of the data storage patterns spaced apart from each other in the first and second directions; and
upper shield lines that extend in the second direction on the data storage patterns and each of the upper shield lines is spaced apart from each other in the first direction,
wherein each of the lower shield lines and each of the upper shield line include a magnetic material.

13. The device of claim 12, wherein e the magnetic material is at least one of cobalt (Co), iron (Fe), or nickel (Ni).

14. The device of claim 12, wherein
a bottom surface of each of the data storage patterns is in contact with a top surface of a corresponding one of the lower shield lines, and
a top surface of each of the data storage patterns is in contact with a bottom surface of a corresponding one of the upper shield lines.

15. The device of claim 12, further comprising:
a lower dielectric layer between the data storage patterns and the wiring dielectric layer; and
lower electrode contacts in the lower dielectric layer and each of the lower electrode contacts electrically connected to a corresponding one of the data storage patterns, the lower electrode contacts penetrating through the lower dielectric layer.

16. The device of claim 15, wherein the lower dielectric layer has a recessed top surface that is recessed toward the substrate between at least two of the data storage patterns.

17. The device of claim 16, further comprising:
lower wiring lines with each of the lower wiring lines between a corresponding one of the lower electrode contacts and a corresponding one of the lower shield line, the lower wiring lines extending in the first direction and each of the lower wiring lines being spaced apart from each other in the second direction; and
upper wiring lines with each of the upper wiring lines between a corresponding one of the upper shield line and a corresponding one of the data storage patterns, the upper wiring lines extending in the second direction and each of the upper wiring lines being spaced apart from each other in the first direction.

18. The device of claim 17, wherein
each of the lower wiring lines is in contact with a corresponding one of the lower shield line, and
each of the upper wiring lines is in contact with a corresponding one of the upper shield line.

19. The device of claim 17, further comprising an upper dielectric layer between the upper wiring lines and the upper shield lines,
wherein the lower wiring lines and the lower shield lines are vertically spaced apart from each other across a portion of the wiring dielectric layer.

20. A magnetic memory device, comprising:
a substrate;
conductive lines on the substrate;
a wiring dielectric layer that covers the conductive lines;
lower shield lines that extend in a first direction in the wiring dielectric layer and each of the lower shield lines spaced apart from each other in a second direction, the first and second directions being crossed with each other and parallel to a top surface of the substrate;
data storage patterns on the lower shield lines and each of the data storage patterns spaced apart from each other in the first and second directions, each of the data storage patterns including a bottom electrode, a first magnetic pattern, a tunnel barrier pattern, a second magnetic pattern, and a top electrode that are sequentially stacked; and
upper shield lines that extend in the second direction on the data storage patterns and each of the upper shield lines are spaced apart from each other in the first direction,
wherein a bottom surface of each of the bottom electrodes is in contact with a top surface of a corresponding one of the lower shield lines, and
wherein a top surface of each of the top electrodes is in contact with a bottom surface of a corresponding one of the upper shield lines.
